(19) United States
(12) Patent Application Publication
(10) Pub. No.: US 2024/0047551 A1
(43) Pub. Date: Feb. 8, 2024

(54) A GRAPHENE/GRAPHENE OXIDE DIODE AND A METHOD OF FORMING THE SAME

(71) Applicant: PARAGRAF LIMITED, Somersham (GB)

(72) Inventor: Robert WALLIS, Somersham (GB)

(73) Assignee: PARAGRAF LIMITED, Somersham (GB)

(21) Appl. No.: 17/773,350

(22) PCT Filed: Nov. 2, 2020
(86) PCT No.: PCT/EP2020/080707

§ 371 Date: Apr. 29, 2022

(30) Foreign Application Priority Data
Nov. 4, 2019 (GB) 1915993.8

(51) Int. Cl. H01L 29/66; H01L 29/16; H01L 29/88

(52) U.S. Cl. CPC H01L 29/6603; H01L 29/1606; H01L 29/88

(57) ABSTRACT

The present invention provides method for forming a diode, the method comprises providing a first graphene layer structure on a first substrate; providing a second graphene layer structure on a second substrate; treating the first graphene layer structure with an oxidant to form a graphene oxide surface thereon; and aligning the second graphene layer structure against the graphene oxide surface of the first graphene layer structure.

The present invention relates to a graphene diode and a method for forming the graphene diode. In particular, a graphene diode that comprises a graphene and graphene oxide layer. The graphene diodes are formed from a graphene and graphene oxide layer which are brought into contact with one another thereby forming a diode with a vertical configuration.

Graphene is a well-known material with a plethora of proposed applications driven by the material's theoretical extraordinary properties. Good examples of such properties and applications are detailed in ‘The Rise of Graphene’ by A. K. Geim and K. S. Novoselev, Nature Materials, Volume 6, 183-191, March 2007 and in the focus issue of Nature Nanotechnology, Volume 9, Issue 10, October 2014.

WO 2017/029470, the content of which is incorporated herein by reference, discloses methods for producing two-dimensional materials. Specifically, WO 2017/029470 discloses a method of producing two-dimensional materials such as graphene, comprising heating a substrate held within a reaction chamber to a temperature that is within a decomposition range of a precursor, and that allows graphene formation from a species released from the decomposed precursor; establishing a steep temperature gradient (preferably >1000° C. per meter) that extends away from the substrate surface towards an inlet for the precursor; and introducing precursor through the relatively cool inlet and across the temperature gradient towards the substrate surface. The method of WO 2017/029470 may be performed using vapour phase epitaxy (VPE) systems and metal-organic chemical vapour deposition (MOCVD) reactors.

Graphene has attracted immense research because of its theoretical properties for use in a wide range of applications which include electronic devices such as diodes since diodes are fundamental electronic devices in many electronic systems.

It has been shown to be possible to form p-n junctions (a necessary feature of typical semiconductor based diodes) with a planar or lateral configuration across the graphene through multiple electrostatic gating, local chemical doping and engineering of substrates. However, this lateral configuration fails to demonstrate a current rectifying effect. That is to restrict the flow of current in one direction and allow the flow of current in the opposite direction (i.e. a diode) in order to allow conversion of alternating current (AC) to direct current (DC). This has been shown to be due to the relativistic nature of the charge carriers in graphene which may tunnel through any potential barrier created by the p-n junction by Klein tunnelling.

A second configuration involves vertical stacking of graphene materials in order to form p-n junctions. Current rectification has been observed by inserting an insulating or semiconducting material between the p and n graphene layers. Graphene p-n Vertical Tunneling Diodes by S. Kim et al. (ACS Nano 2013, Vol. 7, No. 6, 5168-5174) relates to such a graphene based device. CVD grown graphene is transferred onto a Si/SiO₂ substrate and a solution of benzyl viologen (BV) in toluene is spin coated onto the graphene sheet and then annealed. This results in n doping of the graphene sheet and formation of corrugated structures consisting of semiconducting or insulating materials. A second graphene sheet is transferred onto the first n doped graphene sheet and a solution of gold chloride dissolved in nitromethane spin coated onto the second graphene sheet. A second anneal process p dopes the second graphene sheet to create the vertical configuration of n and p doped graphene sheets.

When current (electrons) tunnel through from the n doped graphene sheet to the p doped graphene sheet, the Dirac cone fills up to the charge neutrality point where the density of states tends to zero thereby limiting current flow. When the bias is reversed, electrons flow from the p doped graphene sheet to the n doped graphene sheet with an increasing density of states, allowing current to flow more readily. When the tunnel barrier is too thin, no rectification is observed due to Klein tunnelling. When the tunnel barrier is too thick, all charge flow is inhibited. This method of manufacture is complex, requires hazardous chemicals, and does not provide for easy scale up whilst also having a poor rectification ratio.

All carbon material pn diode by X. Feng et al. (Nat. Commun. 2018, Vol. 9, 3750) relates to a vertically configured graphene based, specifically graphene oxide based, diode. The device is formed from two layers of graphene oxide, one negatively charged (n type doped) and the other positively charged (p type doped). The graphene oxide based p-n diode was fabricated by laminating the two layers of oppositely charged graphene oxide sheets thereby forming a p-n junction. When combined, current rectification was observed with a rectification ratio of about 6. However, the device has a low forward bias current of about 500 nA at 1 V. The method of forming the device involves collecting the functionalised graphene flakes on to a glass substrate which requires extracting the flakes after oxidation and capturing them on a glass substrate which is not an easily scalable process.

US2012/0205606 discloses a non-volatile memory device which may be used in resistive random access memory. The device exhibits conductor like non-rectifying behaviour, rather than operating as a diode over a wide range of voltages with an excellent on/off current ratio, as achieved with the device disclosed herein.

US2015/0206940 discloses graphene p-n vertical tunnelling diodes which rely on doped graphene electrodes.

“Resistive Switching in Al/Graphene Oxide/AI structure”, Panin et al, Japanese Journal of Applied Physics 50 (2011) 070110, discloses RRAM devices which involves a graphene oxide film, made by oxidising graphite, sandwiched between aluminium electrodes.

“Graphene Oxide Thin Films for Flexible Nonvolatile Memory Applications”, Jeong et al, Nano Letters, 2010, 10, 4381-4386, also discloses devices which involves a graphene oxide film, made by oxidising graphite, sandwiched between aluminium electrodes.

There remains a need for improved and better-quality graphene based diodes, in particular graphene based diodes with improved rectification ratios. There also remains a need for an improved method for the provision of such graphene based diodes that are simpler, i.e. that are easier and have fewer process steps and/or which avoid the need to use potentially harmful chemicals. There is also a need for improved diodes that are suitably transparent which may enable their use in certain electronic applications, such as solar cells.

It is an object of the present invention to provide such improved graphene based diodes and methods for forming the same, which overcomes, or substantially reduces the problems associated with the prior art or to at least provide a commercially viable alternative thereto.

Accordingly, in a first aspect there is provided a method for forming a diode, the method comprises:
providing a first graphene layer structure on a first substrate;
providing a second graphene layer structure on a second substrate;
treating the first graphene layer structure with an oxidant to form a graphene oxide surface thereon; and
aligning the second graphene layer structure against the graphene oxide surface of the first graphene layer structure.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The inventors have discovered a method for forming an improved graphene based diode comprising a graphene layer structure aligned against a graphene oxide surface of a second graphene layer structure, i.e. a graphene/graphene oxide diode.

Graphene layer structures are grown on substrates, one of which is oxidised to form graphene oxide which may be carried out by the Hummers method (originally developed for graphite). Oxidation results in a band gap proportional to the degree of oxidation. The band gap is posited to create a current rectification whereby there is a lack of density of states in one bias direction, but not in the other. The method as described herein eliminates the requirements for any graphene transfer processes which allows for easy scale up production. The method accordingly involves fewer process steps.

A graphene layer structure may be prepared by methods such as liquid exfoliation, solid exfoliation, oxidation-exfoliation-reduction and intercalation-exfoliation. These methods typically employ bulk graphite as a raw starting material relying on exfoliation (in a top-down approach) as the method by which individual graphene sheets are separated from the bulk. If a free graphene layer is provided then this can be adhered to a substrate. Graphene may be prepared using chemical vapour deposition (CVD) techniques. Preferably, a graphene layer structure is prepared by vapour phase epitaxy (VPE) and/or by metal-organic chemical vapour deposition (MOCVD). Preferably, graphene is prepared by the method disclosed in WO 2017/029470, i.e. an MOCVD-type technique.

MOCVD is a term used to describe a system used for a particular method for the deposition of layers on a substrate. While the acronym stands for metal-organic chemical vapour deposition, MOCVD is a term in the art and would be understood to relate to the general process and the apparatus used therefor and would not necessarily be considered to be restricted to the use of metal-organic reactants or to the production of metal-organic materials. Instead, the use of this term indicates to the person skilled in the art a general set of process and apparatus features. MOCVD is further distinct from CVD techniques by virtue of the system complexity and accuracy. While CVD techniques allow reactions to be performed with straight-forward stoichiometry and structures, MOCVD allows the production of difficult stoichiometries and structures. An MOCVD system is distinct from a CVD system by virtue of at least the gas distribution systems, heating and temperature control systems and chemical control systems. An MOCVD system typically costs at least 10 times as much as a typical CVD system. CVD techniques cannot be used to achieve high quality graphene layer structures.

MOCVD can also be readily distinguished from atomic layer deposition (ALD) techniques. ALD relies on step-wise reactions of reagents with intervening flushing steps used to remove undesirable by products and/or excess reagents. It does not rely on decomposition or dissociation of the reagent in the gaseous phase. It is particularly unsuitable for the use of reagents with low vapour pressures such as silanes, which would take undue time to remove from the reaction chamber. MOCVD growth of graphene is discussed in WO 2017/029470.

The method of WO 2017/029470 provides two-dimensional materials with a number of advantageous characteristics including: very good crystal quality; large material grain size; minimal material defects; large sheet size; and self-supporting. Graphene is a well-known term in the art and refers to an allotrope of carbon comprising a single layer of carbon atoms in a hexagonal lattice. The term graphene used herein encompasses structures comprising multiple graphene layers stacked on top of each other. The term graphene layer is used herein to refer to a graphene monolayer. Said graphene monolayers may be doped or undoped. The graphene sheets and graphene layer structures disclosed herein are distinct from graphite since the layer structures retain graphene-like properties.

Accordingly, it is preferred that the first and second graphene layers are provided on the first and second substrates respectively by MOCVD. It is an advantage of the present invention that graphene may be grown directly onto the substrate eliminating the requirement of graphene transfer processes reducing the complexity of device manufacture. Accordingly, in a preferred embodiment, the method as described herein does not involve a graphene transfer step. That is, the method does not need to involve transfer of graphene or graphene oxide from one substrate to another substrate.

Each graphene layer structure may comprise one or more graphene layers. Preferably, the graphene layer structure comprises from 1 to 100 graphene layers, more preferably from 1 to 30 graphene layers.

In one embodiment, the second graphene layer structure is doped, preferably n-type doped. The n-type doping of the second layer may give rise to reduced Fermi level pinning.

The first and second graphene layer structures as described herein are provided on first and second substrates, respectively. Exemplary substrates that may be used in the method as described herein include silicon (Si), silicon carbide (SiC), silicon dioxide (SiO₂), sapphire (Al₂O₃) and III-V semiconductor substrates or combinations of two or more thereof. III-V semiconductor substrates may include binary III-V semiconductor substrates such as GaN and AlN and also tertiary, quaternary and higher order III-V semiconductor substrates such as InGaN, InGaAs, AlGaN, InGaAsP. Preferably, the first and or second substrate is selected from silicon, silicon carbide, silicon dioxide, silicon nitride, sapphire and a III-V semiconductor.

Preferably, one or both of the first and second substrates are transparent. That is, transparent substrates are those that allow transmission of visible light through the material. Preferably, transparent substrates allow greater than 50% transmission of visible light, more preferably greater than 75%, greater than 90% and most preferably greater than 95% transmission. Advantageously, the use of transparent substrates, preferably sapphire, may allow the use of such diodes in wearable and flexible electronics, photovoltaic applications and display technologies. Moreover, when compared to conventional semiconductor diodes, the active device region of the diode as described herein is extremely thin with a thickness of <10 nm as opposed to >100 μm for bulk semiconductor devices.

The method as described herein involves the step of treating the first graphene layer structure with an oxidant to form a graphene oxide surface thereon. Oxidation of the first graphene layer structure results in the transfer of oxygen species such as hydroxyl, epoxy and carboxyl groups onto the surface of the first graphene layer structure. Graphene oxide is typically synthesised by the oxidation-exfoliation of graphite. Using strong oxidising agents, oxygen species are introduced into the graphite structure which expand the layer separation to enable exfoliation (such as by sonication), but also make the material hydrophilic enabling dissolution in water and other organic solvents. Graphene oxide is known to those skilled in the art. The degree of oxidation may vary depending on the oxidising conditions used, temperatures and duration of oxidation. Typically, graphene oxide has a ratio of carbon to oxygen of from 2:1 to 5:1. Preferably, the first graphene layer structure having a graphene oxide surface thereon has a ratio of carbon to oxygen of 2:1 to 3:1. The inventors have found that these ratios enable the generation of a band gap without making the graphene too electrically insulative, such as with pure graphene oxide.

The method as described herein involves oxidation of the first graphene layer structure (rather than graphite) provided on a substrate. Treating the first graphene layer structure with an oxidant may be carried out using equivalent methods as those known for graphite oxidation-exfoliation, in other words with the use of an oxidising solution. In particular, it is preferable to use a modified Hummer's method using the graphene coated substrate in place of graphite. Preferably, the method involve treating the graphene coated substrate with an oxidising solution comprising sulphuric acid, potassium permanganate and sodium nitrate. Accordingly, the method involves the direct oxidation of graphene without having to isolate the graphene oxide which forms from oxidation of graphite in conventional syntheses.

The treatment with an oxidant forms a graphene oxide surface. That is the exposed surface of the graphene layer structure provided on a substrate is oxidised generating various oxygen functionalities such as epoxide, carbonyl, carboxyl and hydroxyl groups. The oxidation results in the generation of a band gap with a size proportional to the degree of oxidation (which may be related to the oxygen content). Accordingly, when the first graphene layer structure is a doped graphene layer structure (which therefore already has a non-zero band gap), a different level of oxidation is required to achieve the same final band gap as that achieved when compared to starting from an undoped graphene layer structure having a nominally zero band gap. In either circumstance, the band gap of the treated graphene layer structure having a graphene oxide surface is preferably from about 0.01 eV to about 5 eV, more preferably from about 0.05 eV to about 3 eV and most preferably from about 0.1 eV to about 2 eV.

Without wishing to be bound by theory, the inventors have found that current rectification observed in the final diode results from the band gap creation. Accordingly, there is a lack of density of states in one bias direction restarting the flow of current whilst there is an increased density of states in the other direction allowing the flow of current in said direction. The inventors have also found that the formations of oxygen-based groups (which extend above the planar surface of the graphene layer structure) create a tunnel barrier enabling rectification properties.

The method as described herein further includes the step of aligning the second graphene layer structure (which is an untreated graphene layer structure provided on a substrate) against the surface of the first graphene layer structure having been treated to provide a graphene oxide surface thereon.

The step of aligning the two graphene layer structures is to physically contact the surface of each graphene layer structure with one another. This step is preferably carried out whilst minimising lateral forces acting on the graphene layer structures which may otherwise result in the shearing of the layers. It is preferable that the first and second graphene layer structures are retained together mechanically, such as by a clip or a clamp in order to afford a robust diode. The structure may be retained by wrapping with a transparent tape and/or encasing in polydimethylsiloxane.

In a preferred embodiment, at least one of the first graphene layer structure and the first substrate, and at least one of the second graphene layer structure and the second substrate, are provided with one or more electrical contacts for connecting the diode to an electrical circuit. Electrical contacts may be provided by painting with a conductive metal-containing composition such as a conductive silver paint.

When electrical contacts are provided, the step of aligning the first and second graphene layers structures is preferably carried out such that the electrical contact of the at least one of the first graphene layer structure and the first substrate is not in contact with the electrical contact of the at least one of the second graphene layer structure and the second substrate in order to allow formation of an electrical circuit.

Preferably, the method further comprises processing the aligned first and second graphene layer structures to form a plurality of diodes. This may comprise creating multiple patterns on each graphene layer structure and bringing the first and second graphene layer structures into contact with one another whilst ensuring that the electrical contacts are not in contact with one another.

In a further aspect there is provided a diode obtainable by the method as described herein.

### FIGURES

The present invention will now be described further with reference to the following non-limiting Figures, in which:

FIG. 1 shows an exemplary relationship of current and voltage for a graphene/graphene oxide diode prepared by the method as described in Example 1.

FIG. 2 shows a graphene/graphene oxide diode as described herein.

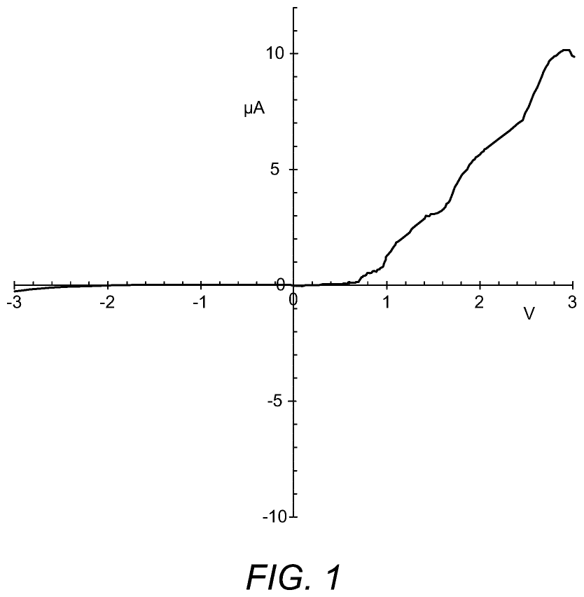

FIG. 1 illustrates the relationship between current and voltage when applied across an exemplary diode formed by the method as described in Example 1. FIG. 1 illustrates the strong rectifying effect of the diode, i.e. the diode allows current to flow in a forward bias above 1 V and at a current of about 10 μA and 3 V whilst allowing negligible current to flow in the reverse direction. The diode restricts flow of current at least up to about −3 V. In other words, the breakdown voltage for the diode is a voltage greater than −3 V. This result illustrates the improved rectification ratio achievable by the diode prepared by the method as described herein.

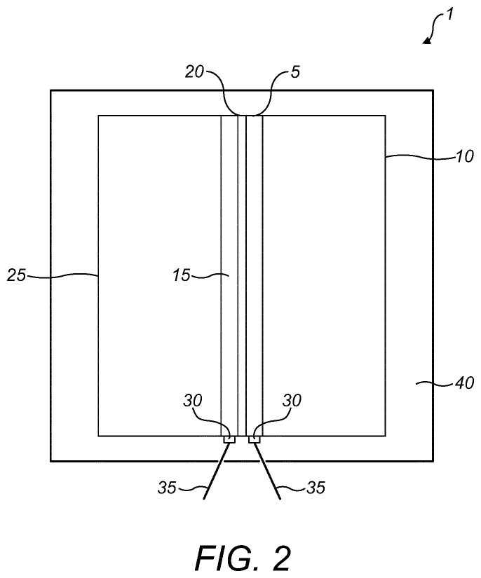

FIG. 2 shows a graphene/graphene oxide diode 1. The diode 1 comprises a first graphene layer structure 5 provided on a first substrate 10. The diode 1 further comprises a second graphene layer structure 15, having a graphene oxide surface 20, provided on a second substrate 25. The first and second substrates 10, 25 are preferably sapphire, but other semiconductor materials would be suitable. The first and second graphene layer structures 5, 15 preferably comprise graphene layer structures of 2-6 layers and are, accordingly, substantially transparent.

The graphene oxide surface 20 is in contact with the first graphene layer structure 5. The graphene oxide surface 20 may be held in contact with the first graphene layer structure 5 by an adhesive (not shown).

Electrical contacts 30 are provided on the first and second graphene layer structures 5, 15. These are connected to electrical traces 35 for connection with a broader electrical circuit (not shown).

An inert polymer coating 40 is applied around the diode structure to insulate and provide structural integrity to the diode 1.

### EXAMPLES

### Example 1

A graphene layer structure is provided on a sapphire wafer. The graphene coated sapphire wafer is cut into pieces no smaller than 2 mm by 5 mm. The aspect ratio of the cut wafers should be such that electrical contacts can be placed onto the wafer whilst also allowing clamping to an equally sized wafer with electrical contacts without the electrical contacts of the two wafers touching.

Next, 15 mL of sulphuric acid are measured into a beaker followed by 0.06 g of sodium nitrate which is then stirred for 5 minutes. Then, 0.36 g of potassium permanganate (KMnO₄) is added to the mixture and stirred for 5 minutes.

2 mL of this mixture is decanted into a vial to which a further 2 mL of sulphuric acid is added before stirring for 1 minute. A cut wafer is then submerged in the solution for 10 seconds. The wafer is removed, rinsed with 2 portions of deionised water and allowed to dry under a nitrogen flow.

An electrical contact is painted using a conductive silver paint onto the corner of a dried wafer which is then allowed to dry for 10 minutes. The same process is carried out on an untreated wafer.

The graphene surface of the untreated graphene coated sapphire wafer is aligned and clamped with a clip to the graphene oxide surface of the treated wafer. The alignment is such that the silver electrical contacts are not touching one another and carried with minimal lateral forces applied to the graphene layers which may otherwise shear them off.

Electrical wires are attached to the electrical contacts for a connection into an electrical circuit and the diode's properties ascertained.

As used herein, the singular form of “a”, “an” and “the” include plural references unless the context clearly dictates otherwise.

The foregoing detailed description has been provided by way of explanation and illustration, and is not intended to limit the scope of the appended claims. Many variations in the presently preferred embodiments illustrated herein will be apparent to one of ordinary skill in the art, and remain within the scope of the appended claims and their equivalents.

1. A method for forming a diode, the method comprising:
providing a first graphene layer structure on a first substrate;
providing a second graphene layer structure on a second substrate;
treating the first graphene layer structure with an oxidant to form a graphene oxide surface thereon; and
aligning the second graphene layer structure against the graphene oxide surface of the first graphene layer structure.

2. The method according to claim 1, wherein the first and second graphene layer structures are retained together mechanically and/or with an intervening adhesive.

3. The method according to claim 1, wherein at least one of the first graphene layer structure and the first substrate, and at least one of the second graphene layer structure and the second substrate, are provided with one or more electrical contacts for connecting the diode to an electrical circuit.

4. The method according to claim 1, wherein the oxidant is an oxidising solution.

5. The method according to claim 1, wherein the first and second graphene layers are provided on the first and second substrates respectively by MOCVD.

6. The method according to claim 1, wherein the method further comprises processing the aligned first and second graphene layer structures to form a plurality of diodes.

7. The method according to claim 1, wherein the first and/or second substrate is selected from silicon, silicon carbide, silicon dioxide, silicon nitride, sapphire and a III-V semiconductor.

8. A diode obtainable by the method according to claim 1, the diode comprising:
a first graphene layer structure on a first substrate, the first graphene layer structure having a graphene oxide surface;
a second graphene layer structure on a second substrate;
wherein the surface of the second graphene layer structure is aligned against and in contact with the graphene oxide surface of the first graphene layer structure.

9. The diode of claim 8, wherein at least one of the first graphene layer structure and the first substrate, and at least one of the second graphene layer structure and the second substrate, have one or more electrical contacts for connecting the diode to an electrical circuit.

10. An electrical circuit comprising the diode of claim 9, wherein the circuit comprises electrical wires attached to the electrical contacts.

11. The method according to claim 1, wherein the first and/or second graphene layer structures are provided on the first and second substrates respectively by liquid exfoliation, solid exfoliation, oxidation-exfoliation-reduction or intercalation-exfoliation.

12. The method according to claim 4, wherein the oxidising solution comprises sulphuric acid, potassium permanganate and sodium nitrate.
